(19) United States
(12) Patent Application Publication
(10) Pub. No.: US 2016/0260631 A1
(43) Pub. Date: Sep. 8, 2016

(54) HOLDING AND ROTATING APPARATUS FOR FLAT OBJECTS

(71) Applicant: RUDOLPH TECHNOLOGIES GERMANY GMBH, Mainz (DE)

(72) Inventors: Felix Möllmann, Eltville am Rhein (DE); Dietrich Drews, Selzen (DE); Holger Wenz, Orbis (DE)

(73) Assignee: RUDOLPH TECHNOLOGIES GERMANY GMBH, Mainz (DE)

(21) Appl. No.: 15/028,175

(22) PCT Filed: Oct. 6, 2014
(86) PCT No.: PCT/EP2014/071307

§ 371 Date: Apr. 8, 2016

(30) Foreign Application Priority Data
Oct. 8, 2013 (DE) 10 2013 220 252.0

(51) Int. Cl. H01L 21/687; G01N 21/01; G01N 21/95; H01L 21/68

(52) U.S. Cl. CPC H01L 21/68707; H01L 21/68721; H01L 21/68728; H01L 21/68764; H01L 21/68; G01N 21/01; G01N 21/9501; G01N 2201/023

(57) ABSTRACT

The invention relates to a holding and rotating apparatus for flat objects which define an object plane, having a gripper device that is rotatable about a rotation axis, said gripper device having a plurality of edge grippers and being designed to fix the object in a defined position in all spatial directions, the object plane being oriented perpendicularly to the rotation axis in said position, and having a rotary drive coupled to the gripper device, said rotary drive being designed to set the gripper device with the object in rotation about the rotation axis. The invention is characterized by a device for distance positioning, said device being designed to apply a supporting force, directed perpendicularly to the object plane, to the object in a contactless manner.

The invention relates to a holding and rotating apparatus for flat objects that define an object plane, especially for semiconductor wafers, with a gripping device rotatable about a rotational axis that has a plurality of edge grippers and that is set up to fix the object or the wafer in a position defined in all three dimensions, wherein the object plane is aligned perpendicular to the rotational axis, and with a rotary drive coupled with the gripping device, which is designed to rotate the gripping device holding the object around the rotational axis. In particular the invention relates to a wafer inspection system with such a holding and rotating apparatus and with an inspection unit disposed on the access side and directed toward the object.

The invention also relates to a method for holding and turning flat objects, especially semiconductor wafers, with the following features: gripping an object in its edge area using a gripping device, wherein the object is fixed in a position defined in all three dimensions, and turning the gripping device together with the object around a rotational axis oriented perpendicular to an object plane defined by the object.

In the following, the coordinates “x” and “y” will also be used to designate the object plane, and consequently the term “x-y plane” will be used. The direction of the rotational axis perpendicular to the x-y plane will also be called the “z-direction.”

The gripping device of the relevant class is known, for example, from Patent Application Publication DE 10 2004 036 435 A1. It has the said plurality of edge grippers mentioned, each of which comprises a support element and a pressure element between which the object is clamped at its edge region. It also has an actuation mechanism including an actuator, also designated as a gripping mechanism, with which the edge grippers can be actuated to grip or release the object.

The gripping device with its plurality of edge grippers grips the object so that its position is fixed immovably and is clearly defined within the holding and rotating apparatus and thus in all three spatial directions relative to the holding and rotating apparatus. For this purpose, for example in the case of disc-shaped objects, such as semiconductor wafers, a plurality of three or more edge grippers is preferably provided.

The gripping mechanism, as known, is arranged together with the rotary drive on one side of the object plane, the “holder side,” so that the opposite “access side,” aside from parts of the edge grippers that engage in the edge region of the object, usually the support elements, is freely accessible.

The edge area of the object in the aforementioned in the case of the aforementioned semiconductor wafers is defined only as a transition area from the flat surfaces of the top and bottom sides to the surrounding edge (“apex”). In this area the wafer has a chamfer, also known in technical language as a “bevel.” Contact with the flat surfaces is avoided, since the usable area of the wafer that must not be damaged or contaminated begins here.

In the initially-mentioned wafer inspection system, the wafer surface of the freely accessible access side is examined for defects and/or contamination in a high-resolution inspection process. The surface roughness of the wafer can also be determined in the inspection. The result of the inspection initially serves to qualitatively determine the quality of the inspected object. Furthermore any defects or contaminants discovered can be parameterized and passed along to subsequent processing modules for process control. In this way the quality of the manufacturing process can be continuously monitored and expensive production defects can be avoided from the beginning.

For the sake of completeness it should be noted that during wafer inspection, for reasons related to handling, the inspection of the top, bottom and edges will differ. This is related to the fact that the wafer is usually transferred from one process step to the next in horizontal alignment and turning over the wafer is avoided. Therefore the same sides of the wafer are always oriented upward or downward. The present invention is used for inspecting both the top and bottom sides.

After the object has been securely gripped in the edge area by the gripping device and fixed, the gripping device together with the object is rotated using the rotary drive, wherein the object moves relative to the inspection unit directed at the object plane. In this way the surface of the object can be scanned by the inspection unit. For this purpose the inspection unit preferably has a scanning head, which is moved along a path relative to the object that is essentially radial relative to the rotational movement and parallel to the object plane. Depending on the method of manipulation of the scanning head, the path is preferably rectilinear or curved. Scanning of the complete surface of the object is accomplished by superimposing the rotational movement of the object on the movement of the scanning head along the path, for example along a spiral or arc-shaped path.

With progressive development of the manufacturing of semiconductor wafers, their size is increasing, which naturally generates a wish for inspection devices with which correspondingly large surfaces may also be inspected. However, this is not trivial. Since the thickness of the semiconductor wafer does not increase proportionally with the diameter and especially does not increase proportionally with the surface area, the rigidity decreases significantly with increasing size. This leads to considerable deformation of a horizontally arranged wafer clamped at the edges. Thus in the case of a wafer with a diameter of, for example, 450 mm and a thickness of, for example, 925 μm, even at rest a gravity-induced sag of about 600 μm in the z-direction can be observed. Whereas the measurement plane is actually two-dimensional and flat, the object describes a curved surface. The change in distance from its edge to its center typically amounts to about 600 μm and is thus large enough for the surface of the wafer to move away from the focal point of a conventional optical inspection system, so that reliable inspection for defects is not possible in this condition.

It should be noted at this point that “object plane” is defined here as the theoretical plane in which an idealized object clamped in the gripping device would be oriented. In the case of the “ideal wafer,” this plane is two-dimensional and flat. The actual semiconductor wafer described deviates from this in the above-mentioned degree. In addition the invention is not limited to such two-dimensional, flat objects, but can also be applied to flat objects with an inherently curved (ideal) surface.

Furthermore it was observed in the case of semiconductor wafers that, as a result of the centrifugal forces arising during rotation of the gripping device and the object, the air enclosed between the gripping device and the object on the holder side is accelerated radially outward, leading to a pressure difference between the holder side and the gripping side of the object. If the gripping device is arranged on the top of the wafer, a force resulting from the pressure difference opposes the gravitational force acting on the wafer and can compensate for it. However, the pressure difference depends on the speed of rotation of the object. Based on the general desire to make the inspection process as rapid as possible, one would like to be able to select the highest possible rotation speeds. In this case, pressure differences can arise based on the simultaneously increasing size of the semiconductor wafer, which said differences generate a considerably higher force than that of gravity. Then the wafer, with the given constellation, will be mechanically distorted opposite from gravity in the direction of the holder side, and thus will arch upward. The deformation would be even greater in the case of an arrangement of the holder side on the wafer underside, so that the gravitational force and the pressure force would be additive.

Furthermore, in many cases a highly differentiated deformation pattern develops. In addition to the sag, specifically the clamping forces induced by the gripping device cause a non-rotationally symmetric deformation in the object, which is superimposed on the sag.

Finally, because of the rotary movement, the deformation is not static. If this deformation is not symmetrical relative to the rotational axis or if eccentric fixation of the object exists or if in general the combination of the rotational impetus, the gripping device and the object causes imbalance, this will result in vibrations of the object in the z-direction as well.

In the case of such time- and location-dependent deformations, it is difficult to achieve tracking by the scanning head to compensate for the changes in distance between the scanning head and the object surface.

Thus the goal of the present invention is to further develop a holding and rotating apparatus, a wafer inspection system using this, and a method of the initially-mentioned type such that for example wafer inspection is possible in a simple way and without tracking of the scanning head.

The object is accomplished with a holding and rotating apparatus according to claim 1, a wafer inspection system according to claim 17 and a method according to claim 18.

The holding and rotating apparatus of the initially-mentioned type according to the invention comprises a distance positioning device arranged to apply a supporting force directed perpendicular to the object plane against the object without contact.

Correspondingly the method of the invention provides that a supporting force is applied against the object perpendicular to the object plane without contact by means of the distance positioning device.

The supporting force acts as a repelling force proceeding from the device for distance positioning (“against the object”). With the aid of the supporting force it is possible to damp any vibration of the object occurring in the z-direction and/or to smooth the object so that its surface coincides with the (ideal) object plane except for practically negligible deviations. “Contactless” here means without physical contact between parts of the mechanism for distance positioning and the object in order to prevent contamination, damage or friction insofar as possible. Theoretically all effective methods of levitation, which may be fundamentally based on different action principles, for example ultrasound levitation or an air cushion, come under consideration for this purpose.

A holding and rotating apparatus with a device for contactless distance positioning is known from Patent Application Publication DE 10 2006 045 866 A1. Here, however, in contrast to the present invention, any contact with the top and bottom of the object is avoided and therefore edge grippers are avoided. Edge grippers according to the invention are characterized in that they impose a holding or clamping force onto the object which serves to fix the object in the holding- and rotating apparatus so that its position is defined in all three dimensions of space relative to the holding- and rotating apparatus. The effective direction is thereby primarily not relevant. The holding- or clamping force can, for example, be induced into a radial direction of the object plane, whereby immobilization in z-direction is effected by positive locking or friction locking connection. However, the clamping forces preferably have a component in z-direction, i.e. in direction of the rotational axis, as known for example from document DE 10 2004 036 435 A1 mentioned herein before. The present problem of more or less complex deformation and/or vibration of the object due to reduced clamping forces in the case of DE 10 2006 045 866 A1 does not arise.

As is known from DE 10 2004 036 435 A1, the gripping device of the holding and rotating apparatus according to the invention preferably has a gripping mechanism that actuates the edge grippers and together with the rotary drive is arranged on a holder side of the object plane, so that an opposite access side of the object plane is freely accessible, aside from parts of the edge grippers.

This arrangement simplifies access to one side of the object for manipulation (inspection, measurement and/or working) thereof. Basically the orientation of the gripping device in space is freely selectable. In practice, however, for alreadymentioned handling reasons in the case of inspection devices for semiconductor wafers, the same side of the wafer is always positioned upward or downward. The upward facing side is usually the so-called front side, and the downward facing side is the back side, and therefore a distinction is also made between front side and back side inspection. The orientation of the gripping device therefore can determine whether the device is set up for front side inspection in the case of the access side located at the top or for back side inspection in the case of the access side located at the bottom. The holding and rotating apparatus according to the invention, however, can also be designed such that inspection of the front and back sides is possible simultaneously and without turning over, as will be explained further in the following.

The device for distance positioning is preferably arranged on the holder side of the object plane.

This has the advantage that the access side is also free from parts of the distance positioning apparatus and thus remains fully freely accessible. This arrangement comes under consideration if the supporting force acting against the object intended to compensate for a force acting in the direction of the holder side and deforming the object, for example gravity in the case of an upwardly facing access side or, in the case of rapidly rotating objects, the initially described pressure difference that forms during rotation.

On the basis of, for example, rotation speed-related or object-related, nonconstant operating conditions, the supporting force is more advantageously adjustable.

Preferably the holding and rotating apparatus according to the invention has a distance sensor which is set up to determine the distance of an object fixed by the gripping device and rotated around the rotational axis from a measurement plane parallel to the object plane. Particularly preferably this distance sensor is set up to determine the distance in a space-resolved manner.

For example in the initially-described wafer inspection system, the distance sensor can be formed by the inspection unit aligned with the object plane itself. Alternatively it can also be designed as a separate sensor or as a profilometer, which is specifically provided for determining topographical information on the object surface. The distance sensor can for example be embodied in the form of at least one capacitive sensor, a laser triangulation sensor or a confocal distance center. The distance sensor is preferably suitable and aligned to determine both the amplitude and frequency of any vibration of the object.

The sensor can be an individual sensor set up in a fixed position relative to the gripping device with which the distance at the mid-point of the object or, if the sensor is arranged eccentrically relative to the rotational axis, on a circular path is determined. It can also, as the scanning head of an inspection unit, be provided movably on a path relative to the gripping device. Several sensors may also be distributed over the measurement surface to simultaneously determine the distance at the mid-point and/or on several circular pathways and thus generate a differentiated three-dimensional image.

A preferred further development of the holding and rotating apparatus designed in this way provides a control unit that is coupled with the distance sensor and the device for contactless distance positioning and is set up to guide the distance positioning device such that the distance of the object from the measurement plane determined has minimal variations over space and/or time.

The sensor and the control unit can be configured such that the distance is determined before the beginning of the inspection or processing procedure (manipulation) of the object or once, several times, intermittently or continuously during the rotation of the object. The distance signal in the first case is used for calibrating the holding and rotating apparatus, which is followed by a single consideration of a deviation of the distance from a theoretical value in the case of controlling the set-up of the device for distance positioning. In the case of a continuous distance measurement, the distance signal can be used as a feedback signal for regulating the distance. In the intermediate cases of repeated distance measurement, the distance signal can be used as a feedback signal for regulating the distance. In the intermediate cases of repeated distance measurement the distance signal can be used to adjust the control data for setting up the distance positioning as necessary.

To achieve the best possible vibrational damping and flattening of the object, the device for contactless distance positioning is preferably set up to press against the object with the supporting force in selected areas.

This can be implemented in a three-dimensionally constant manner in the simplest case. If the shape of the objects to be manipulated is always the same, for example a disc-shaped wafer of constant diameter, it may be sufficient to select a device for contactless distance positioning with a fixed, predetermined geometry in such a manner that its action is optimized at a fixed (maximal) rotation speed (in the operating state) relative to the smoothing and vibrational damping. Such a geometry, for example, may be an annular shape or a disc shape, which is preferably arranged symmetrically to the rotational axis.

In a three-dimensionally adjustable variant embodiment of the invention the device for contactless distance positioning may have several active areas for supplying the supportive force, which can be controlled separately from one another and thus for example are suitable for suppressing or compensating spatially or systematically for more complex vibrational modes and/or deformations of the object.

According to a particularly preferred embodiment of the invention the device for contactless spatial positioning has a sonotrode array with at least one ultrasound generator and at least one sonotrode coupled with the ultrasound generator and aligned on the object plane.

A sonotrode is defined here as a mechanism in which, by means of the ultrasound generator, a high frequency mechanical vibration can be induced and which has a radiating surface over which the mechanical vibration is emitted to the environment. According to the invention the radiating surface is then arranged such that the vibration emitted to the environment (air preferably comes under consideration as the coupling medium) is aligned onto the object plane. By means of this vibration a force field is generated which pushes on the object. This method of contactless distance positioning utilizes the principle of ultrasonic levitation, which was also already described in Patent Application Publication DE 10 2006 045 866 A1. More accurately stated, this involves the principle used in an ultrasonic air cushion. In this process the surrounding air or the surrounding process gas is compressed by the ultrasound. A considerable advantage of this principle is that no external air supply is necessary, which for example could present a risk of contamination.

This principle means that the radiating surface of the sonotrode device is arranged in the near-field distance to the object plane. In this near-field area the force field has a large gradient in the z direction, so that the equilibrium of forces between the levitation force and the force to be compensated for (gravity and/or lift) fixes the object in a sharply delimited three-dimensional area.

The near field is defined as the immediate area in front of the radiating surface of the sonotrode, which is distinctly smaller than the wavelength of the vibration in the coupling medium (preferably air). The distance of the radiating surface from the object plane or the object surface for vibrations in the range below 100 kHz is a few millimeters at most, and for vibrations in the range of 1 GHz is in the range of a few μm. Preferably the radiating surface of the sonotrode array is positioned at a distance of between 50 μm and 500 μm from the object plane or the object surface. A preferred ultrasound frequency for achieving an adequate degree of efficacy is preferably in the range of 20 kHz to 100 kHz.

According to a preferred embodiment the sonotrode array exhibits a planar radiating surface aligned in parallel to the object plane.

The parallelism is required because of the fact that the (ideal) object plane is already fully determined by the gripping device. In order for the repelling force not to attempt to force the object into a position that differs from this, first of all accurate parallelism is required. This is all the more required, the larger the radiating surface of the sonotrode array becomes. Therefore it is advantageous to provide a small radiating surface measured against the surface area of the object. In the case of a circular surface, the diameter of the radiating surface of the sonotrode array therefore should be no more than half the diameter of the object.

Another preferred embodiment provides that the radiating surface of the sonotrode array is subdivided into at least two partial surfaces and particularly preferably that a corresponding number of ultrasonic generators is provided, which are set up to individually drive the at least two partial surfaces of the sonotrode array.

“Partial surface” can define an arbitrary section of the radiating surface, which can be actuated or driven in this way. For practical purposes this design means that the sonotrode array comprises at least two sonotrodes, also called “individual sonotrodes” in the following, and at least one ultrasound generator assigned to each sonotrode. The smallest partial surface of the sonotrode array then corresponds to the radiating surface of an individual sonotrode. However, the sonotrode array can also exhibit a plurality of individual sonotrodes and ultrasound generators. In such a case single or several (not all) of the sonotrodes combined into a cluster can form partial surfaces of different shapes and sizes.

With a plurality of individually energizable sonotrodes, an approximate lack of plane-parallel array of the radiating surface of the total sonotrode array can be electronically compensated in a simple manner in that for example the amplitude of the ultrasonic signal is varied in a positionally dependent manner in such a way that an inclined potential plane is produced which compensates for the change in distance.

However, this is not the only advantage of a sonotrode array with several separately controllable partial surfaces. For example in this way it is also possible to compensate for symmetrical deformations of the object in a targeted manner and/or to damp higher-order vibrations in a targeted manner if the at least two separately energizable partial surfaces are used in combination with the above-discussed distance sensor plus control unit.

In an additional advantageous embodiment of the invention, the sonotrode array has a radiating surface that is arranged symmetrically to the rotational axis. This arrangement takes the symmetry of the rotational movement into account.

An alternative embodiment of the device for contactless distance positioning comprises a fluid flow generator and a nozzle arrangement coupled with the fluid flow generator and directed toward the object surface.

With such a device, air or another process gas is blown against the object, which in this way experiences a repulsive force. In other words an air cushion is formed between the nozzle arrangement and the object and the object floats on this. An arrangement of this type is also described in Patent Application Publication DE 10 2006 045 866 A1.

All of the aforementioned considerations on a differentiated control and sensor system for targeted suppression of vibrations and flattening of deformed objects apply equally here. For example the nozzle arrangement can have several nozzles, each controllable with fluid streams of different strengths, so that a targeted, locally differing repulsive force acts on the object to compensate for more complex deformations of the object. However, this arrangement and this method have natural limitations due to the fact that the reaction rate of the action principle is lower compared with that of the ultrasonic air cushion. Thus for example at high rotational speeds of the object, the use of this apparatus may be disadvantageous.

Additional features and advantages of the invention will be explained in the following based on exemplified embodiments. These show:

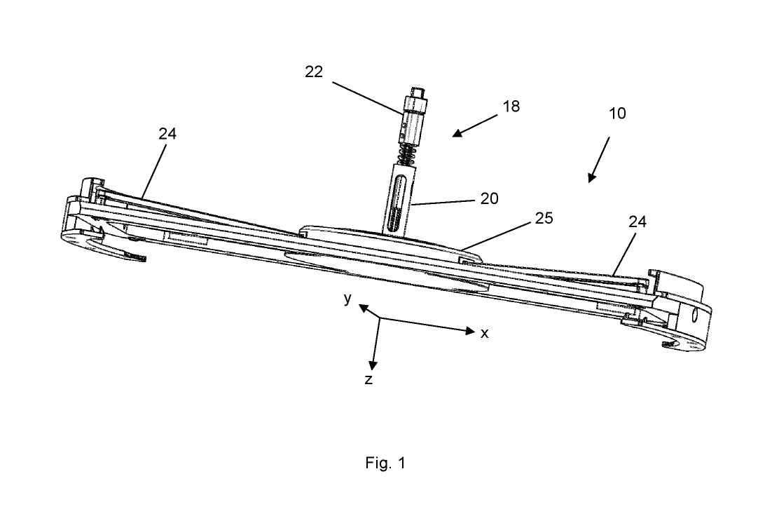

FIG. 1 a perspective view of the rotatable gripping device;

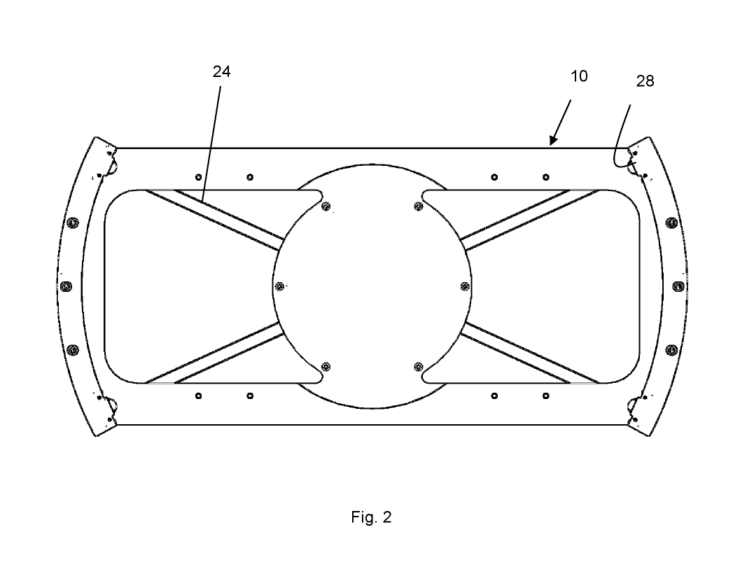

FIG. 2 a bottom view of the gripping device according to FIG. 1;

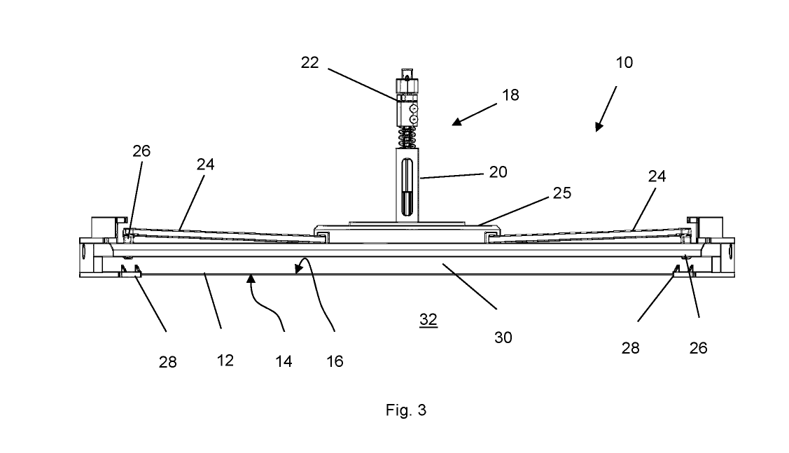

FIG. 3 a side view of the gripping device according to FIG. 1;

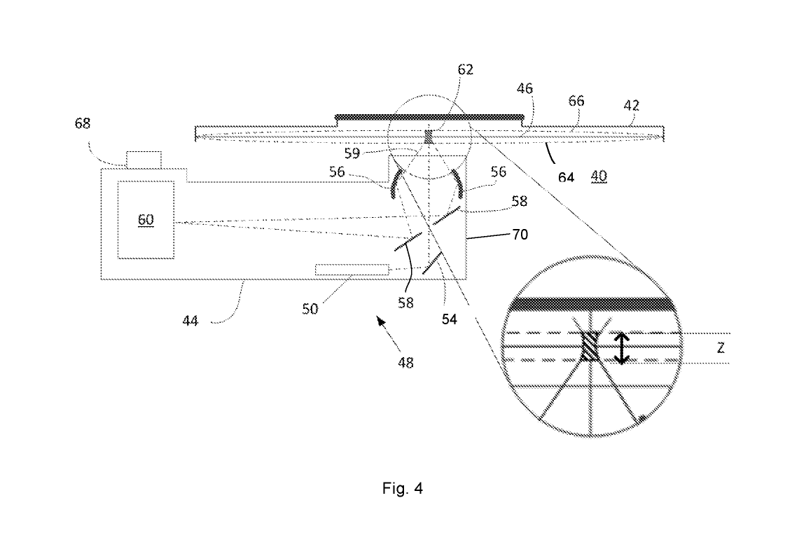

FIG. 4 a side view of a wafer inspection system without apparatus for distance positioning to illustrate wafer deformation;

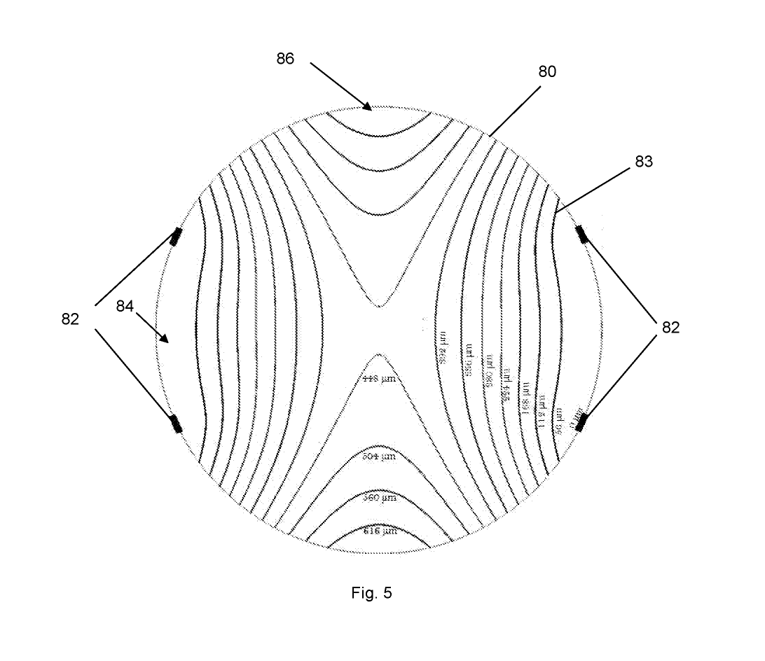

FIG. 5 a two-dimensional graph for representing the degree of deformation of a clamped-in wafer at rest;

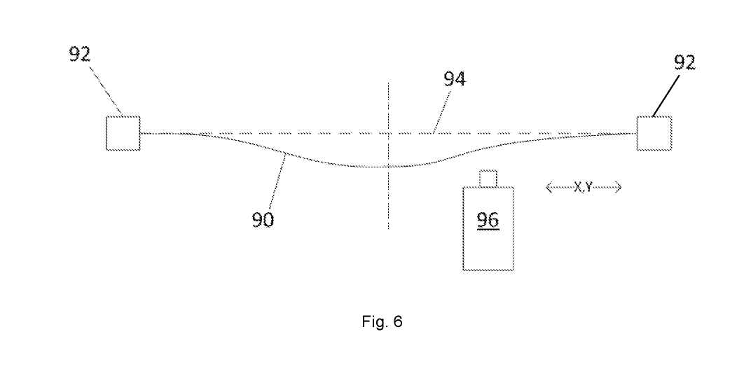

FIG. 6 a schematic side view of a clamped-in wafer at rest;

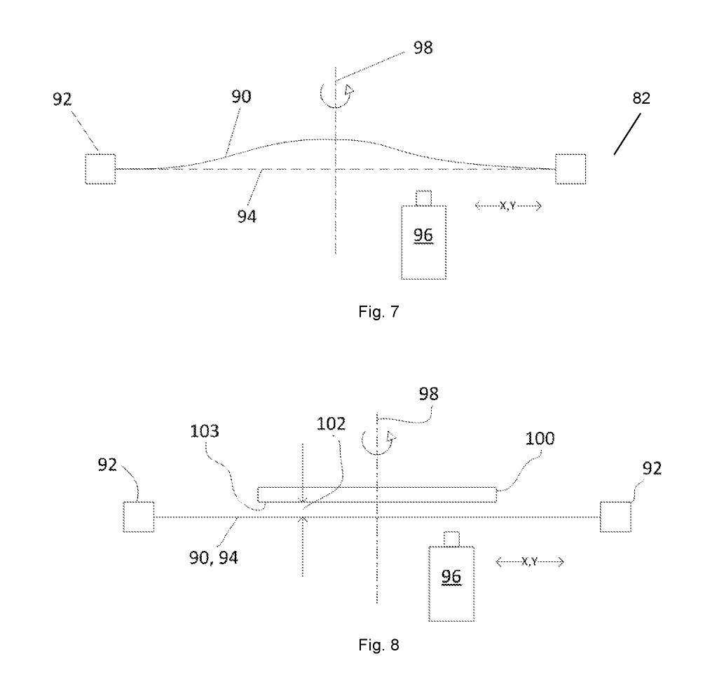

FIG. 7 a schematic side view of a clamped-in wafer during rotation;

FIG. 8 a schematic side view of a clamped-in wafer during rotation and using a first device for distance positioning;

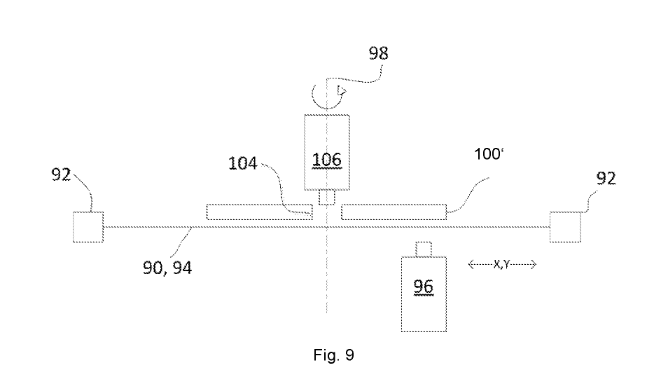

FIG. 9 a schematic side view of a clamped-in wafer during rotation and using a second device for distance positioning;

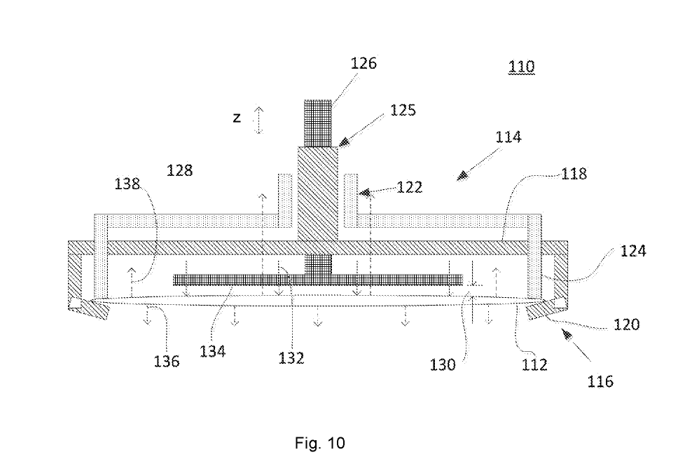

FIG. 10 a schematic side view of the holding and rotating apparatus for flat objects according to the invention;

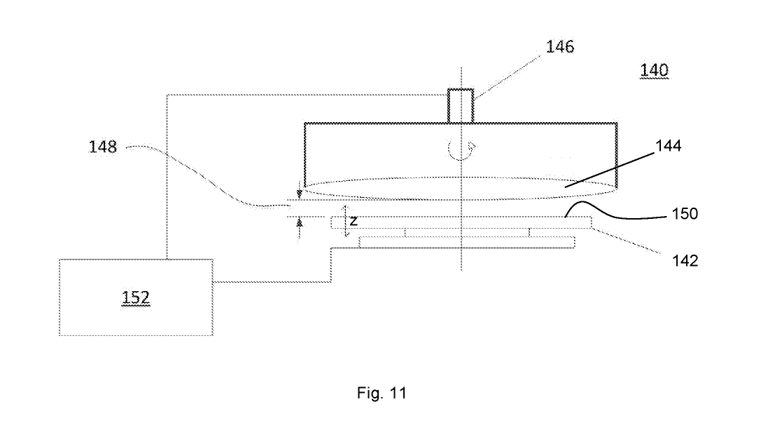

FIG. 11 a side view of another embodiment of the holding and rotating apparatus for flat objects;

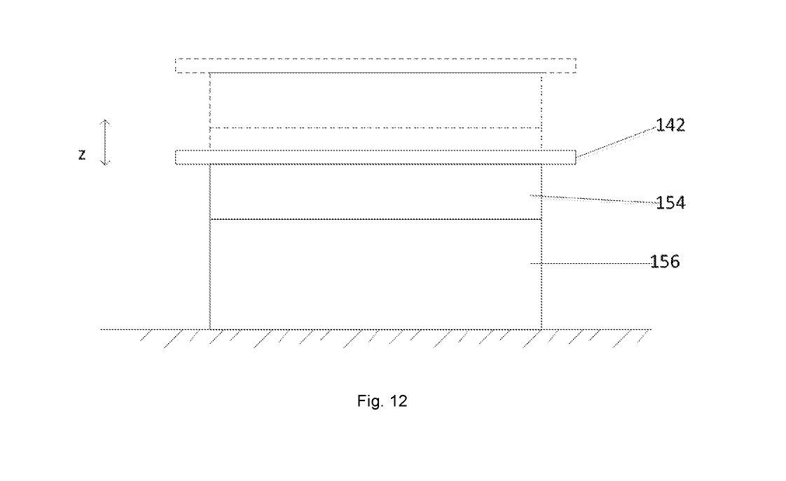

FIG. 12 a sectional enlargement of the device for distance positioning from FIG. 11 in two positions;

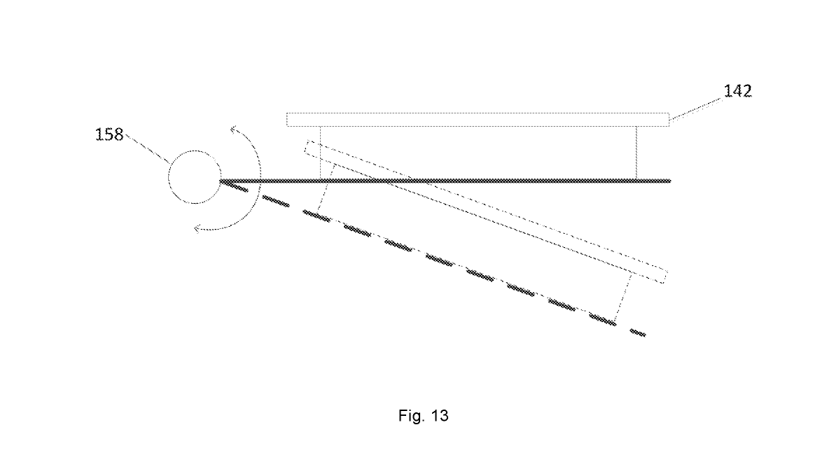

FIG. 13 an alternative embodiment of the device for distance positioning in two positions;

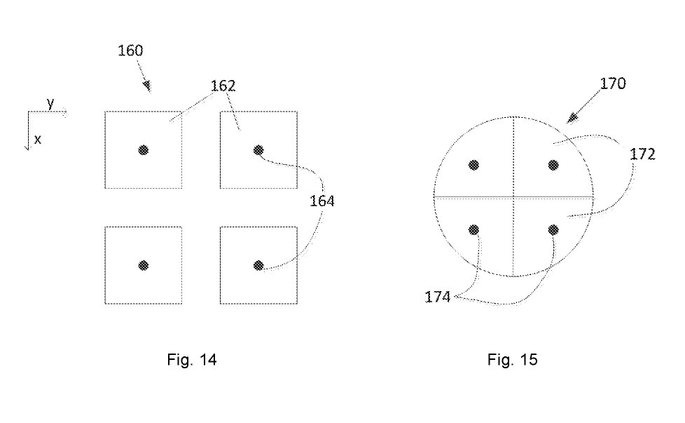

FIG. 14 a schematic top view of the first embodiment of a sonotrode array;

FIG. 15 a top view of a second embodiment of a sonotrode array;

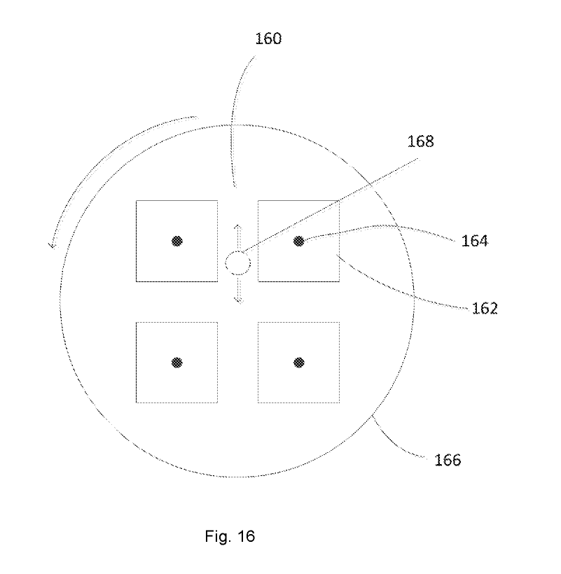

FIG. 16 a top view of the sonotrode array according to FIG. 14 with a movable distance sensor;

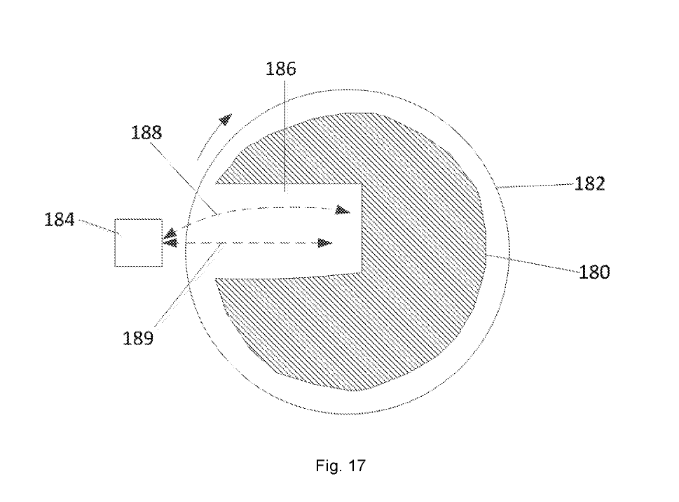

FIG. 17 a top view of a third embodiment of a sonotrode array with a one-piece radiating surface;

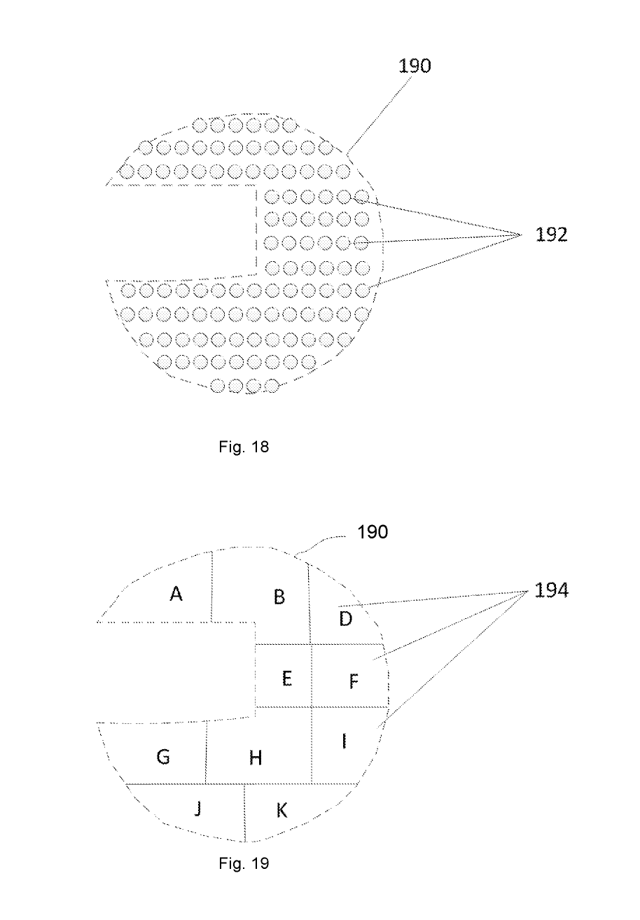

FIG. 18 a top view of a fourth embodiment of a sonotrode array with a plurality of individual sonotrodes or partial surfaces;

FIG. 19 a top view of a fifth embodiment of a sonotrode array with partial surfaces of different geometry;

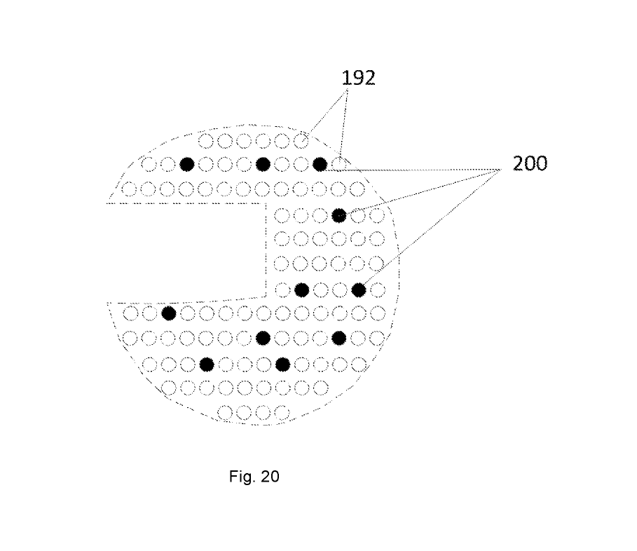

FIG. 20 a top view of a sixth embodiment of a sonotrode array with a plurality of distance sensors;

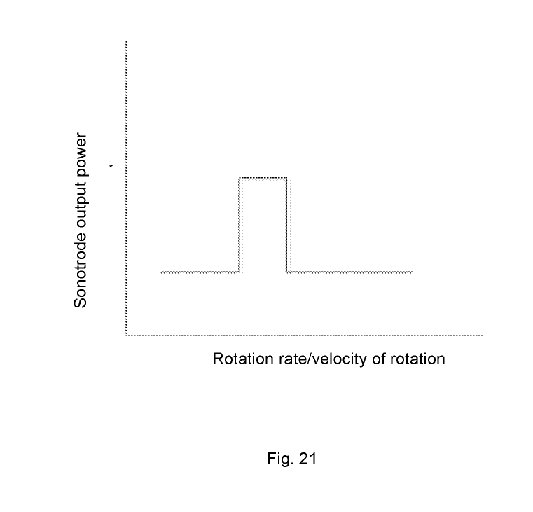

FIG. 21 a first energization curve for a sonotrode and

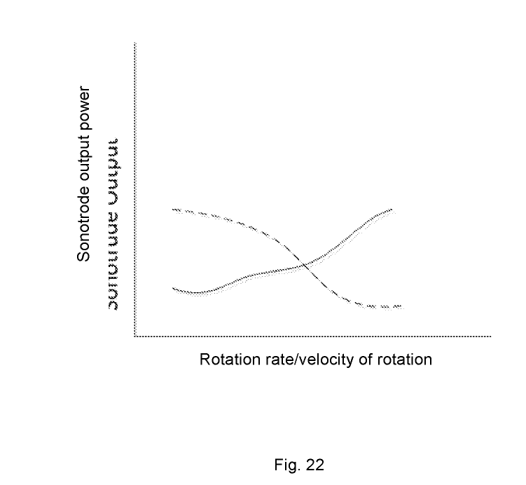

FIG. 22 a second energization curve for a sonotrode.

In FIGS. 1 to 3 a gripping device 10 which is a component of the holding and rotating apparatus for flat objects according to the invention, especially for semiconductor wafers, is shown. A semiconductor wafer 12 placed in the gripping device is shown in FIG. 3. The gripping device 10 is shown in the overhead position, so that the semiconductor wafer 12 has an access side 14 essentially freely accessible from below and a holder side 16 facing the gripping device 10. In normal wafer handling the downward pointing side is the gripping side and the upward pointing side is the front side of the wafer, so that the gripping device 10 in the overhead position shown here serves for inspecting the back side. The gripping device 10, however, could also be used in the rotated orientation without restriction.

The gripping device 10 has a central suspension 18, which simultaneously covers the rotational shaft 20, over which the rotary movement in the gripping device 10 is initiated and is transferred with this to the semiconductor wafer 12. At the top of the rotational shaft 20 a connecting rod 22 projects out of the rotational shaft 20, and is part of the gripping mechanism. Also part of the gripping mechanism are four holding arms 24, which are pivotable in a manner not shown within a housing 25 of the gripping mechanism and can be actuated by means of the connecting rod 22. On their free outer end the holder arms 24 have cylindrical pressure elements 26, which upon actuation pivot the connecting rod out of the release position as shown into a clamping position. In the clamping position they are located with their pressing surfaces at the lower end against the upper edge area of the semiconductor wafer 12 and press it with its lower edge area against respectively assigned support elements 28. Above the support elements 28, oblique centering surfaces are provided, along which the semiconductor wafer can glide into a centered position upon placement in the gripping device 10. As was previously described, the pressing elements and support elements ensure that the semiconductor wafer 12 is only contacted in its edge area, preferably only in the area of its chamfer or bevel and is simultaneously fixed in a defined position in all directions of space (x, y, z) relative to the gripping device 10.

The pressing surfaces of the pressing elements 26 and the pressing surfaces of the supporting elements 28 are preferably made of a nonreactive material relative to the semiconductor wafer material (silicone, gallium, arsenite, etc.), so that the material does not leave behind any residues or particles on the wafer surface. In addition the material of the pressing elements 26 and the supporting elements 28 is softer in the contact area than the material of the semiconductor wafer.

If the gripping device 10 is set into rotation together with the fixed semiconductor wafer 12, because of frictional effects the gas located in the intermediate space 30 (generally air) is likewise set into rotation. As a result, centrifugal forces arise, which accelerate the air outward in the radial direction, so that depending on the rotation rate, a more or less large differential pressure forms between the air in the intermediate space 30 and that in the outer space 32 especially below the semiconductor wafer 12.

In FIG. 4 a section of a wafer inspection system 40 with a schematically simplified holding and rotating apparatus 42 and an inspection unit 44 is shown. The holding and rotating apparatus 42 is once again arranged overhead, so that a wafer 46 clamped therein is freely accessible from its underside for access to the inspection unit 44. The inspection unit 44 comprises an arm 48 in which a light source 50, for example in the form of a laser diode, for generating an outgoing light beam is arranged. The light beam is deflected on a first deflecting mirror 54 in such a way that it strikes the underside of the semiconductor wafer 46. If a defect is present there, for example in the form of a scratch, a nick, an indentation or a particle, on or in the surface, the light is scattered from this. The scattered light 59 is deflected by means of an optical collection system, in this case by means of mirrors 56 and additional deflecting mirrors 58, to a detector unit 60 in the arm 48 in such a way that no direct reflection of the initial light beam strikes it. The defect recognition in this case thus also takes place for example by dark field measurement.

In contrast to the simplified representation of FIG. 4, additional optical elements, especially lens systems, can be arranged within the beam path. In particular the arrangement of the collecting mirrors 56 can be partially or completely replaced by lens systems.

As can be seen based on the beam course of the scattered light 59, essentially only beams which originate from the focal point 62 of the collecting optics 56 are deflected to the detector unit 60. The device is usually arranged such that the focal point is located in the z-direction in the object plane, or more accurately, onto the surface of an ideally flat-clamped wafer 46.

Based on gravity on one hand and based on the pressure difference that becomes established above and below the wafer 46 during rotation on the other hand, depending on the rotation speed, a resulting force acts on the wafer which deforms the wafer in one direction or another. At a low rotation speed the wafer will sag due to gravity and will describe the curve 64 shown by the broken line on the bottom. At high rotation speeds the wafer will bulge upward because of the pressure difference and display a contour with the upper curve 66. In both extreme cases the surface of the wafer 46 to be examined will be located distinctly outside of the focal point 62, so that scattered light under these conditions will only be imaged on the detector unit 60 at greatly reduced intensity. This can lead to misinterpretation of the defect detected or to overlooking defects altogether. Therefore it is even necessary to readjust the position of the focal point 62 depending on the deformation of the semiconductor wafer 46 in the z-direction or to ensure, as the present invention does, that the semiconductor wafer 46 is held in the object plane as accurately as possible.

The arm 48 is connected over an articulated joint 68 with a housing, not shown, on which the holding and rotating apparatus is also suspended. At the upper end of the arm is the scanning head 70, which forms part of the arm 48 and in which the essential optical components for guiding the light are located. The arm is rotatably suspended on the articulated joint 68, so that during a pivoting movement of the arm the scanning head 70 moves along a circular arc section that is essentially radial to the rotational axis of the holding and rotating apparatus 42. This pivoting movement superimposed on the rotary movement of the semiconductor wafer 46 makes it possible to scan the total surface of the semiconductor wafer underside.

In FIG. 5 for example, gravitational deformation of a large, disc-shaped semiconductor wafer 80 with a diameter of 450 mm and a thickness of 925 μm is shown, which is clamped in the gripping device 10 according to FIGS. 1 to 3 at a total of 4 approximately point-shaped positions 82. It is apparent on the basis of contour lines 83 that the semiconductor wafer 80 is deformed in a saddle shape from its highest elevation 84 to its lowest depression 86 and thus reaches a difference in height of more than 600 μm.

Deviating from the deformation shown in FIG. 5, for example, in an arrangement of three edge grippers that are equidistant in the circumferential direction, deformation of the object with triple symmetry occurs. Basically it can be assumed that with increasing number of edge grippers the position of the object edge is determined more accurately and performs the flexion of the object in one direction or another. However it should be noted that it is basically desirable to minimize the contact of the edge grippers and the total contact surface between the edge grippers and the object surface, which would interfere the most accurately defined determination of the object position possible by edge grippers.

The presentations in FIGS. 6 to 9 which follow show in a schematic, highlysimplified manner a side view of a holding and rotating apparatus with an object 90 clamped in it in various operational states. The status of a sagging object 90 when the gripping device is standing still is shown again in FIG. 6. In this side view the object 90 is shown between two radially opposite edge grippers 92, wherein as a result of gravity it hangs down relative to the plane of the object 94. The extent of the deviation is admittedly exaggerated for purposes of illustration. In addition to the gravity-induced sagging of the wafer, secondary effects are also superimposed. For example the clamping forces exerted on the marginal area of the object 90 are to be mentioned, which first clamp the object essentially horizontally in the vicinity of the edge gripper. To a first approximation, with sufficiently small clamping points, a uniform sag represents reality well enough.

In addition, for illustration a scanning head 96 is shown in FIG. 6 below the semiconductor wafer 90; it can be moved in the x- and/or y-direction in a measurement plane parallel to the object plane 94. It is recognizable that the sagging object 90 extends in the center between the edge grippers 92 with its underside close to the measurement plane of the scanning head 96 and is farther away from it in the marginal area. In actuality in the case of real inspection devices the difference in height of a sagging wafer will be on the order of magnitude of the normal distance of the scanning head from the surface to be inspected, so that there is a risk of the underside of the wafer coming into contact with the scanning head, which can result in damage to the semiconductor wafer 90 and thus to considerable material losses.

In FIG. 7 once again the situation of an object bulging upward because of a rotational movement around the rotational axis 98 is shown in a simplified manner. The deformation is due to the pressure difference explained above between the object 90 and the gripping device, not shown here. Here also it is indicated that as a result of the fixation by the edge grippers 92 the wafer in the marginal area is initially clamped essentially parallel to the object plane 94 and begins to show elastic deformation toward the center only at some distance from the edge grippers 92.

In FIG. 8 the holding and rotating apparatus is shown for the first time with an arrangement for distance positioning 100. The semiconductor wafer 90 rotates around the central rotational axis 98. The lifting force resulting according to FIG. 7 and deforming the wafer in the embodiment of the invention shown here is compensated by an opposing supporting force by means of the distance positioning device 100. This repelling supporting force is applied without contact in the area of the center from above against the semiconductor wafer 90, as will be clarified by the gap 102 between the object plane 94 and an effective surface 103 of the distance positioning apparatus 100. “Effective surface” here designates the generalization of the radiating surface in the case of a sonotrode array as a device for distance positioning.

The supporting force (depending on the rotation speed of the gripping device) is adjusted such that ideally it identically compensates for the force effect of the pressure difference, so that the semiconductor wafer 90 coincides with the object plane 94.

In the example shown here the device for distance positioning 100 has a distinctly smaller diameter (≦50%) in the x-y direction than the object 90. In most cases the configuration is adequate for applying a counter-force compensating for the lifting force on the wafer. However, in instances in which the wafer shows a tendency toward less symmetrical deformations and/or toward higher order vibrations, it may be necessary to apply the upward directed supporting force over a larger surface fraction of the object 90 and/or to act on the surface of the object with locally and/or chronologically variable supporting force to bring this into a flat form.

As was previously mentioned, a device for distance positioning with a diameter of more than 50% of the object diameter is already disadvantageous even because merely a slight incorrect positioning of its active surface 103 relative to the object plane 94 perpendicular to the rotational axis 98 leads to an undesirable, non-uniform action of force on the object 90, the position of which is otherwise defined by its fixation in the marginal area. Therefore the dimensions of the device for distance positioning 100 should ideally be as small as possible and as large as necessary to be able to support the semiconductor wafer 90 within the framework of the accuracy required for the intended manipulation.

An alternative embodiment of the device for distance positioning 100′ is shown in FIG. 9. This shows a rotationally symmetric annular geometry with a central opening 104. The opening 104 offers the possibility for access of a distance sensor 106 to the top of the semiconductor wafer 90. The distance sensor 106 is fixed in position in the embodiment shown in FIG. 9 and aligned with the center of the object 90. It is set up to monitor a relative distance to the object surface in the center thereof during the rotation and to record a change in distance. The distance signal obtained can be sent to a control unit and be used to drive the device for distance positioning 100′ such that the distance found to the wafer center corresponds to a predetermined target value at which the center of the object 90 comes to lie in the object plane 94. In many applications this positioning may already be accurate enough. Damping of vibrations can also be achieved in this way. The measurement signal of the distance sensor 106 can be determined continuously and supplied to the control unit as a control variable so that changes over time may also be taken into consideration. In this way, for example, a rate-dependent deformation of the object and the individual deformation behavior of the object will automatically be taken into account. For example, the sensor can only be used permanently or intermittently during the acceleration of the rotary motion to adapt the spatial positioning device in this phase to the rotary movement in a controlled manner. As soon as the target speed is reached and it is assured in some other way that the semiconductor wafer 90 is not exposed to any fluctuating loads, the control loop can be interrupted and the distance positioning device 100′ can operate with constant supporting force.

FIG. 10 shows another schematic representation of the holding and rotating apparatus 110 according to the invention for a flat object 112, for example a semiconductor wafer. The holding and rotating apparatus 110 has a gripping device 114 with edge grippers 116 for gripping the object 112 in its marginal area. On the upper side of the object 112 is the gripping mechanism, consisting essentially of a rotatable and vertically fixed support 118, at the ends of which the supporting elements 120 are located, along with a likewise rotatable and vertically movable actuation mechanism 122 for the pressing elements 124 with which the object 112 is pressed against the supporting elements 120. A hollow shaft 125 is connected to the support 118, which is part of a direct drive for the rotational movement, not shown. A cylindrical section of a fixed sonotrode 128, i.e., not rotating along with it, is passed through the hollow shaft 125. At the same time the sonotrode can be made movable in the z-direction to be able to be moved from a loading and unloading point away from the object 112 into an operating state close to the object 112 and back. The sonotrode 128 is shown in the operating position at a small distance 130 from the top of the object 112, which is preferably between 50 and 500 μm. In this range the sonotrode at the preferred ultrasound frequencies of 20 kHz to 100 kHz is located in the near field distance to the object 112. A change in distance of the sonotrode can also be considered during the operation to vary the strength of the supporting force mechanically, as will be explained in further detail in the following.

In the near field a repelling, downward-directed supporting force 132 in the projection area of the radiating surface 134 of the sonotrode 128 acts on the object 112. In the case of overhead arrangement of the holding and rotating apparatus shown here, the direction of action of the supporting force 132 coincides with gravity 136, which likewise pulls the object 112 downward. The supporting force 132 and the gravitational force 136 are directed opposite to a lift or Bernoulli force 138, which is attributable to the above-described pressure differences above and below the object 112. Ideally by selecting a suitable distance 130, a suitable sonotrode geometry, a suitable ultrasonic frequency and a suitable amplitude, the supporting force 132 is adjusted in such a manner that together with the action of gravity, ideally at each point of the object 112 but at least for practical purposes, it compensates for the lifting force 128 such that the actual position of the object corresponds to the theoretical position in the object plane down to tolerable deviations, for example below the measurement sensitivity of an inspection mechanism.

If the device for distance positioning 128, as shown here, is fixed, in other words not turning simultaneously, this has an effect on the flow dynamics of the gas enclosed between the gripping device 114 and the object 112. Likewise the effect of the sonotrode geometry is to be taken into consideration, since for example the annular sonotrode shown in FIG. 9 has different flow dynamics from a closed, round sonotrode and yet again different for example from a sonotrode with a rectangular radiating surface. Therefore in designing the dimensions of the device for distance positioning, along with the required parallelism and in addition to the required supporting force which partially determines the size of the radiating surface, such shape aspects are additional design parameters to be considered.

In FIG. 11 an alternative embodiment of the holding and rotating apparatus 140 is shown, in which the device for distance positioning in the form of a sonotrode 142 is arranged beneath the object 144, but the gripping device 146 remains disposed above the object 144. This arrangement could for example be used when as a result of the construction design no lifting force prevails or this is compensated for in another way or if the lifting force in any case is small enough so that it is unable to compensate for the gravitationally induced sag of the object 144 or if for other reasons for example it is only necessary to damp the vibration of the object.

In this example a variable distance 148 in the z-direction is provided between the radiating surface 150 of the sonotrode 142 and the underside of the object 144, which can be adjusted with the aid of actuators, as will be explained in the following. The adjustment of the distance 148 offers an additional or alternative option for varying the amplitude of the ultrasound and thus the supporting force of the sonotrode and thus the position of the object 144 in a controlled manner. For this purpose a control unit 152 is provided, which for example correlates the rotation speed of the gripping device 146 or a distance sensor signal and the z-position of the sonotrode 142.

At the same time the z-displacement of the radiating surface 150 of the sonotrode 142 permits better access to the gripping device 146, which is made difficult especially with the arrangement of the sonotrode 142 below the object 144 and the gripping device 146 above it. Otherwise it is practically impossible to hand over the object 144 to the gripping device 146 or place it therein because of the small distances in the operating position of the sonotrode 142.

In this regard we refer to FIGS. 12 and 13. As is shown here, the entire sonotrode 142 can be moved away from the object plane in the z-direction in different ways. For this purpose for example in addition to a device 154 for fine adjustment in the z-direction, with which a controlled adaptation of the distance 148 to the displacement of the supporting forces possible, a coarse adjustment device 156 may be provided, with which the sonotrode may be moved by a larger amount from a release or loading and unloading position, shown as a solid line in FIG. 12, to a working or operating position, shown as a broken line in FIG. 12. The coarse adjustment device can have an electric motor drive, for example with a screw drive or a forward-operated cylindrical piston arrangement, and the fine adjustment device may have a piezoelectric actuator and/or a plunger coil or oscillator coil actuator.

In an alternative kinematic embodiment of the coarse adjustment device, the sonotrode 142 can be pivoted from the working position shown as a solid line in FIG. 13 into a loading and unloading position, which is shown as a broken line, around a rotational axis 158.

FIGS. 14 and 15 each show a front view of a sonotrode array in a highly simplified schematic view. The sonotrode array 160 in FIG. 14 has a four-part radiating surface formed by four identical and symmetrically arranged rectangular individual sonotrodes 162. The individual sonotrodes 162 are at equal distances from each other in pairs, far apart, and therefore together form a likewise rectangular radiating surface.

The sonotrode device 170 in FIG. 15 has a circular radiating surface and is likewise symmetrically divided into four equal partial surfaces, each of which is formed by a sonotrode 172 designed as circular segments. In contrast to the sonotrode array 160, the sonotrodes 172 are not spaced apart in the x- and y-directions. An essential difference is the rotational symmetry of the sonotrode array, which is regularly favored in the case of rapidly turning objects, since it does not induce any unwanted excitation of oscillations because of its shape.

In addition the partial surfaces 162 and 172 each have optional apertures 164 and 174 respectively, through which if needed a fluid stream, preferably an air stream, can be directed in a pushing or suctioning manner, against the surface of the object. Thus this involves an additional device for distance positioning, the effect of which can support that of the sonotrode as needed.

The subdivision into several partial surfaces can serve various purposes. Each of the sonotrodes 162 and 172 can be controlled individually if an ultrasound generator is assigned to each of them individually. In this way for example the supporting force can be applied asymmetrically to predetermined partial areas of the object surface in order for example to be able to compensate more systematically for clamping forces irregularly introduced by the edge grippers.

Another aspect of the subdivided radiating surface will be made clear on the basis of FIG. 16, which shows the sonotrode array 160 from FIG. 14. In this view, in addition to the sonotrode array 160, a disc-shaped wafer 166 and a scanning head 168 of an inspection device or a distance sensor is shown, which is movably arranged on the same side of the object plane on which the sonotrode array 160 is also rotated. The distance between the partial surfaces or individual sonotrodes 162 is of such dimensions that the scanning head 168 fits into it. Thus despite the sonotrode it has access to the surface of the object and can even be moved in the radial direction. This makes possible, for example in combination with an arrangement according to FIG. 11, scanning of the object surface from the downward-pointing back side of the object.

FIG. 17 shows another schematic view of an alternative sonotrode array 180 with a one-piece radiating surface, thus an individual sonotrode which has an essentially circular or disc-shaped contour and the center of which coincides with the rotational axis of an object 182 located below it. Furthermore a scanning head 184 of an inspection device is shown, which is arranged on the same side of the object plane as the sonotrode 180. In the radiating surface of the sonotrode 180 a sufficiently large window 186 is provided, in which the scanning head 184 can move relative and parallel to the object surface during the scanning process, so that the total surface of the object 182 can be detected. This relative movement of the scanning head can alternatively take place along an arc-shaped path 188 or a straight line path 189, both of which travel essentially radially relative to the rotational axis.

In a modification of the sonotrode array or sonotrode 180, in FIG. 18 a sonotrode array 190 of the same contour, but with a plurality of individual sonotrodes 192 is shown. The individual sonotrodes each have individual circular partial surfaces, which together form the radiating surface of the sonotrode array 190. The individual sonotrodes 192 can be energized independently of one another if these have ultrasound generators respectively assigned to them. This makes it possible to generate a homogeneous supporting force over the entire radiating surface and to vary this locally if desired. In this way overall an oblique force field or a point application of force can be generated or a combination of arbitrary individual sonotrodes into partial surfaces with arbitrary geometry inside the grid of the individual sonotrodes can take place. Especially the oblique force field makes possible simple electronic compensation for any possible non-parallelism of the sonotrode array to the object plane.

FIG. 19 shows a sonotrode array 190 of the same contour as before, in which partial surfaces 194 with different geometries are illustrated in a symmetric arrangement. These partial surfaces can be virtual, in other words each of the partial surfaces 194 can for example be formed by an operational combination (cluster) of individual sonotrodes 192 from FIG. 18. Naturally, the partial surfaces may also be physically asymmetric in their arrangement and geometry if the application requires this. However, naturally this design is basically less flexible than that of the example from FIG. 18.

A further development of the sonotrode array from FIG. 18 is shown in FIG. 20. This differs only in that several distance sensors 200 are arranged between the individual sonotrodes 192, and these may exhibit a uniform or non-uniform distribution over the sonotrode surface (in this case, non-uniform). The plurality of distance sensors 200 make it possible to determine the distance between the object and the measurement plane over a plurality of distributed measurement points or during the rotation of the object, over a plurality of circular pathways, so that a practically complete image of the deformation of the object is obtained and a very systematic compensation of this deformation in spatial as well as time respects is possible. In this case a mechanism for moving the distance sensor can be dispensed with, which decreases the cost of the apparatus.

The distance sensors 200, as in the other examples, may for example be laseroptic triangulation sensors, capacitive sensors or confocal distance sensors.

The establishment of suitable operating parameters (in the case of the inspection mechanism with sonotrode array as a device for spatial positioning, consisting for example of the rotation speed of the object, the amplitude and frequency of the ultrasound of the sonotrode array or individual sonotrodes and, where adjustment is possible, the distance of the radiating surface from the object plane) can take place empirically, if first of all the topography of the object surface is determined (for example using the aforementioned distance measurement) as a function of each of the parameters, and a minimum deviation of the topography determined from the ideal object plane can be determined iteratively. The result of such a calibration process is a static parameter set that can be taken as the basis for the object types used. However, the parameter set can also be refined regularly or continuously if the distance information, i.e., the information about the topography of the object surface, is checked regularly. Over time this can lead to an improved parameter set. Both of these approaches describe the control of the device according to the invention.

Additional improvement can be achieved by feedback coupling of distance information monitored during manipulation of the object, thus by regulation of the operating parameters. In this way even small differences, for example small dimensional deviations or internal stresses in the material of the object or slight differences in position of the object fixed in the gripping device, which may also occur in the case of constant object types, can be compensated in situ.

The device according to the invention and the method according to the invention make it possible to establish special operating conditions for each object type, which are transferred to the control unit in the form of such an initial parameter set. For example this can be transmitted in integrated form as an independent file or as an addition to other operating parameters, for example control variables for the inspection system or inspection method. For example it can be made accessible to the control unit in the form of an XML operating data set, separately or added to existing XML operating data sets.

The initial parameter set, as well as the topographic information determined, can be input electronically to the control unit, for example a computer, which then performs the control or regulation of the system after programming and optionally also transcribes and outputs the parameter set again.

As was already mentioned in the preceding, several individual sonotrodes which are separately energizable can be used to damp vibrations, higher-order oscillation modes and any deformations of the turning object whatsoever or to compensate for them. In some instances it is possible that weak vibrations or imbalances in the gripping device that rotates the object can induce rhythmic vertical deformations or vibrations in the turning object. Because of the fixed edge area of the object, this type of vibration can theoretically be modeled in the form of a flexible membrane with fixed points. The above-described distance sensor or a profilometer for the inspection unit itself can be used to measure this vibration directly.

Once the vibration is determined, according to the method of the invention a plurality of measures may be taken to combat it. In the simplest case this may be the global application of a spatially and chronologically constant supporting force, i.e., in the case of the sonotrode array, over its total radiating surface. In differentiated applications the supporting force can also be applied in a regularly or chronologically variable manner. In this process not all vibrations or deformations must always be compensated for. It depends in each case on the application (inspection, measurement or processing) to determine the extent to which vibrations or deformations of the object are tolerable.

If sensors—either the distance sensors discussed or acceleration sensors—determine an intolerable degree of vibration, this information can also be used to generate an error signal via the control unit, which forces an automatic stop of the rotation drive or the entire device or at least emits an alarm signal that can lead a user to stop the process.

Otherwise the vibration data determined (amplitude and/or frequency) can be used in the manner described either to change the rotation speed so that the gripping device moves with the object outside of a resonance frequency or otherwise to control the distance positioning device, thus to operate it on a dynamic basis. Therefore the output power of the sonotrodes for example may be increased or decreased by a certain degree to better damp the vibrations.

The sonotrode power of the one or more sonotrodes can be varied continuously depending on the rotation speed, for example in a linear, exponential or sinusoidal fashion, or discontinuously, for example in the form of square wave pulses. Furthermore the sonotrode power of the one or more sonotrodes can be regulated in the form of a complex function which, for example, takes several vibration modes of the object into consideration.

A simple control curve is shown for example in FIG. 21, and two more complex ones are shown in FIG. 22. In these Figs. the respective output powers of the sonotrode/sonotrode array are shown as a function of the rotation speed or rotation rate of the gripping device or of its rotary drive force. The representations are purely qualitative in nature. Quantitative control depends primarily on the geometric details of the devices and the objects and the efficiencies of the electronic components.

If an object or a gripping device with an object, for example, shows a tendency to undergo one or more discrete resonances at certain rotation speeds during the acceleration and thus to exceed predetermined vibration limits, changes in the sonotrode performance can help to damp or effectively suppress these resonant vibrations. Therefore the control unit may be set up to modify the output power of the sonotrode for a certain duration or within a certain rotation speed band, while that of the gripping device with the object passes through the resonance as is shown in the control signal curve according to FIG. 21. After passing through the resonance the sonotrode returns to the original output power.

Any change in the operating parameters, especially those that determine the output power of the sonotrodes, preferably takes place at a certain speed to avoid a sudden change in state of the system and to protect the object. This is taken into consideration in the control curve according to FIG. 22. As an example this shows a complex, non-linear control signal curve for a single sonotrode or a plurality of sonotrodes, which increases as a function of the rotation speed (solid line), and another control curve which decreases as a function of the rotation speed (broken line). The curves are intended to combat a complex vibrational behavior in which the object passes through several vibration modes at variable rotation speeds.

As a result of differences in energization of individual sonotrodes at the same time a chronologically and locally varying, symmetrical or asymmetric force field, for example following the rotational motion of the object, can be configured. Such an asymmetric energization of several partial surfaces or individual sonotrodes can, for example, be used to combat a predetermined or in situ observed vibration or deformation of the object systematically, i.e., in a locally accurate manner, even during rotation.

Thus in summary it is possible to generate output powers of the distance positioning device varying over both time and space and thus to respond in an extremely highly differentiated way to highly complex deformations and vibrations of the object in order to suppress it or to flatten the object in an appropriate manner.

Although all of the above-described exemplified embodiments relate to objects with an ideally two-dimensional object plane, the invention does not rule out devices in which flat objects with three-dimensionally curved object planes are handled. Correspondingly then for example the sonotrode array can have a likewise curved radiating surface.

Although the invention was further explained in the preceding based on examples from wafer inspection, the holding and rotating apparatus according to the invention and the process of the invention can also be used in other processes. For example instead of defect recognition, the holding and rotating apparatus can also be used for measuring objects or surface processing thereof.

In addition, substrates other than semiconductor wafers can be handled with the device and the method. Glass panels may be mentioned as examples. Finally the contour of the object also does not make a difference. Instead of the round disc form shown as an example it can also be polygonal. The sonotrode array can also have other contours as desired within the framework of the invention.

### LIST OF SYMBOLS

10 Gripping device
12 Semiconductor wafer
14 Access side
16 Holding side
18 Suspension
20 Rotary shaft
22 Push rod
24 Holding arm
25 Housing
26 Pressing element
28 Supporting element
30 Interior space
32 Exterior space
40 Wafer inspection system
42 Holding and rotating apparatus
44 Inspection unit
46 Semiconductor wafer
48 Arm
50 Light source
54 Deflecting mirror
56 Light-gathering optics, mirror
58 Passive reflector
59 Scattered radiation
60 Detector unit
62 Focal point
64 Lower curve, sag
66 Upper curve, bulge
68 Articulated joint
70 Scanning head
80 Semiconductor wafer
82 Holding position
83 Contour line
84 Maximum elevation
86 Maximum depression
90 Object
92 Edge gripper
94 Object plane
96 Scanning head
98 Axis of rotation
100, 100′ Distance positioning device
102 Gap
103 Effective surface
104 Opening
106 Distance sensor
110 Holding and rotating apparatus
112 Object
114 Gripping device
116 Edge gripper
118 Support
120 Supporting element
122 Actuation mechanism
124 Pressing element
125 Hollow shaft
126 Cylindrical section
128 Sonotrode
130 Distance
132 Supporting force
134 Radiating force
136 Gravitational force
138 Lift, Bernoulli force
140 Holding and rotating apparatus
142 Sonotrode
144 Object
146 Gripping device
148 Distance
150 Radiating surface
152 Control unit
154 Fine adjustment
156 Coarse adjustment
158 Axis of rotation
160 Sonotrode array
162 (Individual) sonotrode, partial surface
164 Aperture
166 Wafer
168 Scanning head
170 Sonotrode array
172 (Individual) sonotrode, partial surface
174 Aperture
180 Sonotrode array, sonotrode
182 Wafer
184 Scanning head
186 Window
188 Arc-shaped path
189 Linear path
190 Sonotrode array
192 Individual sonotrode
194 Partial surface
200 Distance sensor

1.-28. (canceled)

29. Holding and rotating apparatus for flat objects which define an object plane, the holding and rotating apparatus comprising:
a gripping device rotatable about a rotational axis, wherein the gripping device has a plurality of edge grippers and is arranged to fix the object in a position defined in all three dimensions of space in which the object plane is aligned perpendicular to the rotational axis;
a rotary drive coupled with the gripping device, wherein the rotary drive is arranged to rotate the gripping device with the object around the rotational axis; and
a distance positioning device arranged to apply a supporting force directed perpendicular to the object plane against the object without contact.

30. Holding and rotating apparatus according to claim 29, wherein the gripping device has a gripping mechanism for actuating the edge grippers, and further wherein the gripping mechanism is arranged together with the rotary drive on a holder side of the object plane in such a manner that an opposite access side of the object plane is freely accessible, aside from parts of the edge grippers.

31. Holding and rotating apparatus according to claim 30, wherein the distance positioning device is arranged on the holder side of the object plane.

32. Holding and rotating apparatus according to claim 30, wherein the supporting force is adjustable to at least one of compensating for a force acting in the direction of the holder side and damping oscillation of the object perpendicular to the object plane.

33. Holding and rotating apparatus according to claim 29, further comprising a distance sensor which is arranged to determine a distance of an object fixed by the gripping device and rotated around the rotational axis from a measurement plane parallel to the object plane in a space-resolved manner.

34. Holding and rotating apparatus according to claim 29, wherein the distance positioning device comprises a sonotrode array with at least one ultrasound generator and at least one sonotrode coupled with the ultrasound generator and aligned on the object plane.

35. Holding and rotating apparatus according to claim 34, wherein the sonotrode array has a flat radiating surface that is aligned in parallel to the object plane.

36. Holding and rotating apparatus according to claim 35, wherein the radiating surface of the sonotrode array is arranged in a near field distance to the object plane.

37. Holding and rotating apparatus according to claim 35, characterized in that the radiating surface of the sonotrode array is subdivided into at least two partial surfaces.

38. Holding and rotating apparatus according to claim 37, wherein the at least one ultrasound generator is arranged to drive the at least two partial surfaces of the sonotrode array individually.

39. Holding and rotating apparatus according to claim 29, wherein the distance positioning device comprises a fluid flow generator and a nozzle arrangement coupled with the fluid flow generator and directed toward the object plane.

40. Wafer inspection system comprising:
a holding and rotating apparatus including:
a gripping device rotatable about a rotational axis, wherein the gripping device has a plurality of edge grippers and is arranged to fix the object in a position defined in all three dimensions of space in which the object plane is aligned perpendicular to the rotational axis,
a rotary drive coupled with the gripping device, wherein the rotary drive is arranged to rotate the gripping device with the object around the rotational axis, and
a distance positioning device arranged to apply a supporting force directed perpendicular to the object plane against the object without contact; and
an inspection unit arranged on the access side and directed toward the object plane.

41. Method for holding and turning flat objects, the method comprising:
gripping an object in its edge area by means of a gripping device, wherein the object is fixed in a position defined in all spatial directions;
turning the gripping device together with the object around a rotational axis that is oriented perpendicular to an object plane defined by the object; and
applying a supporting force is applied to the object perpendicular to the object plane without contact by means of a distance positioning device.

42. Method according to claim 41, wherein the gripping device is arranged on a holder side of the object plane, wherein as a result of a centrifugal force produced by the rotation of the gripping device together with the object, a pressure difference develops between the two sides of the object, above and below the object plane.

43. Method according to claim 41, wherein the supporting force at least one of:
combats deformation of the object due to at least one of the pressure difference, gravitational force, and clamping forces induced by the gripping device, and
damps oscillation of the object perpendicular to the object plane.

44. Method according to claim 41, wherein a distance of the object, fixed and rotated around the rotational axis, from a measurement plane parallel to the object plane is determined in a space-resolved manner.

45. Method according to claim 44, wherein the supporting force is modulated as a function of the determined distance in such a manner that the supporting force destructively interferes with the oscillation of the object.

46. Method according to claim 41, wherein the supporting force is applied to the object by means of sound waves radiated from a sonotrode array directed toward the object plane.

47. Method according to claim 46, wherein the fixed object is arranged in a near field of a radiating surface of the sonotrode array.

48. Method according to claim 41, wherein the supporting force is applied to the object by means of at least one stream of air emitted by at least one nozzle directed toward the object plane.
